(19) United States
(12) Patent Application Publication
(10) Pub. No.: US 2006/0176735 A1
(43) Pub. Date: Aug. 10, 2006

(54) Magnetic tunnel junction device and method of manufacturing the same

(76) Inventor: Shinji Yuasa, Ibaraki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(21) Appl. No.: 11/259,371

(22) Filed: Oct. 27, 2005

(30) Foreign Application Priority Data
Jan. 25, 2005 (JP) 2005-16579

(51) Int. Cl. G11C 11/15

(52) U.S. Cl. 365/173

(57) ABSTRACT

The MR ratio of an MTJ device is increased. A single-crystalline MgO (001) substrate 11 is prepared, and then an epitaxial Fe (001) lower electrode (first electrode) 17 with a thickness of 50 nm is grown on a MgO (001) seed layer 15 at room temperature. Annealing is then performed in ultrahigh vacuum (2×10⁻⁸ Pa) at 350° C. A 2-nm thick MgO (001) barrier layer 21 is epitaxially grown on the Fe (001) lower electrode (first electrode) 17 at room temperature, using electron beam evaporation of MgO. A Fe (001) upper electrode (second electrode) 23 with a thickness of 10 nm is then grown on the MgO (001) barrier layer 21 at room temperature, which is successively followed by the deposition of a Co layer 21 with a thickness of 10 nm on the Fe (001) upper electrode (second electrode) 23. The Co layer 21 is used for realizing an antiparallel magnetization alignment by enhancing an exchange bias magnetic field of the upper electrode 23. Thereafter, the above-prepared sample is subjected to microfabrication so as to obtain a Fe (001)/MgO (001)/Fe (001) MTJ device. The density of dislocation defects that exist at the interface between one of the first or the second Fe (001) layer and the single-crystalline MgO (001) layer is not more than 25 to 50 defects/μm.

### BACKGROUND OF THE INVENTION

1. Field of the Invention

The present invention relates to a magnetic tunnel junction device (MTJ device) and a method of manufacturing the same, and particularly to a magnetic tunnel junction device with a high magnetoresistance and a method of manufacturing the same.

2. Description of Related Art

Magnetoresistive random access memories (MRAMs) refer to a large-scale integrated memory circuit that is expected to replace the currently widely used DRAM memories. Research and development of MRAM devices, which are fast and non-volatile memory devices, are being extensively carried out, and sample products of a 4 Mbit MRAM have actually been delivered.

FIG. 7 shows the structure and operation principle of a magnetic tunnel junction device, which is the most important part of the MRAM. As shown in FIG. 7(A), a MTJ device comprises a tunneling junction structure in which a tunnel barrier made of an oxide is sandwiched between a first and a second electrode made of a ferromagnetic metal. The tunnel barrier layer comprises an amorphous Al—O layer (see Non-patent Document 1.). As shown in FIG. 7(A), in the case of parallel magnetization alignment, where the directions of magnetizations of the first and second ferromagnetic electrodes are aligned in parallel, the electric resistance of the device with respect to the direction normal to the interfaces of the tunneling junction structure decreases. On the other hand, in the case of antiparallel magnetization alignment where the directions of magnetizations of the first and second ferromagnetic electrodes are aligned antiparallel as shown in FIG. 7(B), the electric resistance with respect to the direction normal to the interfaces of the tunneling junction structure increases. The resistance value does not change in a general state, so that information “1” or “0” can be stored depending on whether the resistance value is high or low. Since the parallel and antiparallel magnetization alignments can be stored in a non-volatile fashion, the device can be used as a non-volatile memory device.

FIG. 8 shows an example of the basic structure of MRAM. FIG. 8(A) shows a perspective view, and FIG. 8(B) schematically shows a circuit block diagram. FIG. 8(C) is a cross-section of an example of the structure of MRAM. Referring to FIG. 8(A), in an MRAM, a word line WL and a bit line BL are disposed in an intersecting manner, with an MRAM cell disposed at each intersection. As shown in FIG. 8(B), the MRAM cell disposed at the intersection of a word line and a bit line comprises a MTJ device and a MOSFET connected in series with the MTJ device. Stored information can be read by reading the resistance value of the MTJ device, which functions as a load resistance, using the MOSFET. Stored information can be rewritten by applying a magnetic field to the MTJ device, for example. As shown in FIG. 8(C), an MRAM memory cell comprises a MOSFET 100 including a source region 105 and a drain region 103 both formed inside a p-type Si substrate 101, and a gate electrode 111 formed on a channel region that is defined between the source and drain regions. The MRAM also comprises a MTJ device 117. The source region 105 is grounded, and the drain is connected to a bit line BL via the MTJ device. A word line WL is connected to the gate electrode 111 in a region that is not shown.

Thus, a single non-volatile MRAM memory cell can be formed of a single MOSFET 100 and a single MTJ device 117. The MRAM therefore provides a memory device suitable for high levels of integration.
Non-patent Document 1: D. Wang, et al.: Science 294 (2001) 1488.

### SUMMARY OF THE INVENTION

Although there are prospects for achieving MRAMs with capacities on the order of 64 Mbits based on the current technologies, the characteristics of the MTJ device, which is the most important part of MRAM, need to be improved if higher levels of integration are to be achieved. In particular, in order to increase the output voltage of the MTJ device, the magnetoresistance must be increased and the bias voltage characteristics must be improved. FIG. 9(A) illustrates how the magnetoresistance in a conventional MTJ device using an amorphous Al—O as the tunnel barrier changes as a function of bias voltage applied (L1). As shown, in the conventional MTJ device, the magnetoresistance is small and, notably, it tends to drastically decrease upon application of bias voltage. With such characteristics, the output voltage when operation margins are taken into consideration is too small for the device to be employed for an actual memory device. Specifically, the magnetoresistance of the current MTJ device is small at approximately 70%, and the output voltage is also small at no more than 200 mV, which is substantially half the output voltage of a DRAM. This has resulted in the problem that as the level of integration increases, signals are increasingly lost in noise and cannot be read.

As shown in FIG. 9(A), magnetoresistance can be reduced by applying a voltage to the MTJ device, and the degree to which the magnetoresistance decreases is indicated by a term “bias voltage dependence.” Devices whose magnetoresistance decreases sharply are referred to as devices with poor bias dependence, while devices whose magnetoresistance does not decrease much upon application of a voltage are referred to as devices with good bias dependence. Since the output voltage that is obtained when a MTJ device is used in an MRAM is the product of the bias voltage applied to the device and the magnetoresistance upon application of voltage, it is very effective to improve the bias voltage dependence of the MTJ device in order to obtain high output voltages. As shown in FIG. 9(B), as an index for the evaluation of the bias voltage dependence of a MTJ device, a voltage (referred to as “V_{half}”) at which the value of magnetoresistance becomes half as much as the magnetoresistance value in the absence of application of voltage is used. Namely, the greater the V_{half} value of a particular MTJ device, the better the bias voltage dependence of the MTJ device. The V_{half} value of conventional MTJ devices is normally in the range of 300 mV to 600 mV.

It is an object of the invention to increase the output voltage of MTJ devices. It is another object to provide a memory device with a high magnetoresistance for stable operation. Yet another object of the invention is to further increase the output voltage by improving the bias dependence of MTJ devices.

In one aspect, the invention provides a magnetic tunnel junction device of a magnetic tunnel junction structure comprising:

a tunnel barrier layer;

a first single-crystalline ferromagnetic material layer of the BCC structure formed on a first plane of said tunnel barrier layer; and

a second single-crystalline ferromagnetic material layer of the BCC structure formed on a second plane of said tunnel barrier layer;

wherein said tunnel barrier layer is formed of a single-crystalline MgO (001) or a single-crystalline MgOₓ (x<1) layer (to be hereafter referred to as “a single-crystalline MgO layer”),

and wherein the density of dislocation defects that exist at the interface between one of said first or said second ferromagnetic layers and said tunnel barrier layer is not more than 50 defects/μm and preferably not more than 25 defects/μm. In this magnetic tunnel junction device, the spin scattering of tunneling electrons due to magnons or Mg—O phonons is suppressed, so that the bias voltage dependence of magnetoresistance can be improved and higher output voltage can be obtained.

Preferably, the density of dislocation defects that exist at the interface between one of said first or said second ferromagnetic material layers to which a positive bias voltage is applied during operation and said tunnel barrier layer is smaller than the density of dislocation defects that exist at the interface between the ferromagnetic material layer to which a negative bias voltage is applied and said tunnel barrier layer.

In another aspect, the invention provides a magnetic tunnel junction device of a magnetic tunnel junction structure comprising:

a tunnel barrier layer;

a first poly-crystalline ferromagnetic material layer of the BCC structure that is formed on a first plane of said tunnel barrier layer and in which the (001) crystal plane is preferentially oriented; and

a second poly-crystalline ferromagnetic material layer of the BCC structure that is formed on a second plane of said tunnel barrier layer and in which the (001) crystal plane is preferentially oriented,

wherein said tunnel barrier layer is formed of a poly-crystalline MgOₓ (x≦1) layer (to be hereafter referred to as “a poly-crystalline MgO (001)”) in which the (001) crystal plane is preferentially oriented,

and wherein the density of dislocation defects that exist at the interface between one of said first or said second ferromagnetic layers and said tunnel barrier layer (dislocation defects due to crystal grains, and dislocation defects within crystal grains) is not more than 50 defects/μm and preferably not more than 25 defects/μm. In this magnetic tunnel junction device, the spin scattering of tunneling electrons due to magnons or the like is suppressed, so that the bias voltage dependence of magnetoresistance can be improved and higher output voltage can be obtained.

In yet another aspect, the invention provides a magnetic tunnel junction device comprising:

a poly-crystalline MgO (001) tunnel barrier layer;

a first ferromagnetic material layer formed on a first plane of said tunnel barrier layer and comprising an amorphous alloy; and

a second ferromagnetic material layer formed on a second plane of said tunnel barrier layer and comprising an amorphous alloy,

wherein the density of dislocation defects that exist at the interface between one of said first or said second ferromagnetic material layers and said tunnel barrier layer (due to the grain boundaries of the poly-crystalline MgO) is not more than 50 defects/μm and preferably not more than 25 defects/μm. In this magnetic tunnel junction device, the spin scattering of tunneling electrons due to magnons or the like is suppressed, so that the bias voltage dependence of magnetoresistance can be improved and higher output voltage can be obtained.

The invention also provides a memory device that can be stably operated using a single transistor and any of the foregoing magnetic tunnel junction devices as a load of the transistor.

In accordance with the invention, an MTJ device having greater magnetoresistance than that of conventional MTJ devices can be obtained, so that the output voltage of the MTJ device can be increased. This feature of the invention makes it possible to easily achieve higher levels of integration in MRAMs employing MTJ devices. The feature also enables a stable operation of MRAMs.

### BRIEF DESCRIPTION OF THE DRAWINGS

FIG. 1 shows the structure of a MTJ device according to a first embodiment of the invention (FIG. 1(B)), and the energy band structure of Fe (001), which is a ferromagnetic metal (FIG. 1(A)), indicating the E-E_{F} relationship with respect to the [100] direction of the wave-vector space.

FIG. 2(A) to (D) schematically shows a process for manufacturing a magnetic tunnel junction device having a Fe (001)/MgO (001)/Fe (001) structure according to an embodiment of the invention (to be hereafter referred to as “a Fe (001)/MgO (001)/Fe (001) MTJ device”).

FIG. 3(a) shows a RHEED image of a Fe (001) lower electrode (first electrode), and FIG. 3(b) shows a RHEED image of a MgO (001) barrier layer.

FIG. 4 shows the result of observation of the quadrupole mass spectra during the growth of MgO.

FIG. 5 shows the film deposition-rate dependence of oxygen partial pressure during the deposition of MgO.

FIG. 6 shows typical magnetoresistance curves of the Fe (001)/MgO (001)/Fe (001) MTJ device.

FIG. 7 shows the structure of a MTJ device and its operating principle.

FIG. 8 shows an example of the basic structure of a MRAM, with FIG. 8(A) showing a perspective view of the MRAM, FIG. 8(B) showing a schematic circuit diagram, and FIG. 8(C) showing a cross section of a structural example.

FIG. 9(A) shows how the magnetoresistance of a conventional MTJ device having an amorphous Al—O as a tunnel barrier varies depending on an applied bias voltage. FIG. 9(B) shows a definition of V_{half}.

FIG. 10 shows the structure of a MTJ device according to a variation of an embodiment of the invention, the figure corresponding to FIG. 1 (B).

FIG. 11(a) shows a cross-sectional electron microscope image of the Fe (001)/MgO (001) interface, where a crystal lattice can be observed. Dislocation defects are observed in the central portion encircled by a white circle. FIG. 11(b) shows a cross-sectional electron microscope image where columns of crystal lattices are indicated by solid lines so as to facilitate the visual recognition of the structure of dislocation defects.

FIG. 12(a) shows a cross-sectional electron microscope image of an interface when an MgO layer was deposited on the Fe (001) layer at room temperature and at the rate of 0.08 nm/s. High-density dislocation defects are formed at the interface. FIG. 12(b) shows a cross-sectional electron microscope image of the interface when an MgO layer was deposited on the Fe (001) layer at room temperature and at the rate of 0.002 nm/s.

FIG. 13 shows how V_{half} of the Fe (001)/MgO (001)/Fe (001) single-crystalline MTJ device varies when the dislocation defect density is varied.

FIG. 14 shows how the maximum output voltage (Vₒᵤₜ) of the Fe (001)/MgO (001)/Fe (001) single-crystalline MTJ device varies when the dislocation defect density is varied.

FIG. 15(A) shows the second-derivative conduction spectrum (bias voltage dependence of d²V/dI²) of a MTJ device having a dislocation defect density of 25 defects/μm at the interface in an antiparallel magnetization alignment. FIG. 15(B) shows the second-derivative conduction spectrum (bias voltage dependence of d²V/dI²) of a MTJ device having a dislocation defect density of 100 defects/μm at the interface in an antiparallel magnetization alignment.

FIG. 16(a) to (d) shows a mode of crystal growth when a MgO (001) layer is stacked on the Fe (001) layer.

FIG. 17 shows the film-deposition rate dependence of the dislocation defect density at the interface when the MgO layer was deposited on the Fe (001) layer at the substrate temperature of 100° C.

FIG. 18(a) schematically shows how dislocation defects are formed at the interface when a single-crystalline MgO (001) layer was stacked on a single-crystalline Fe (001) layer. At the interface, only dislocation defects that have been formed so as to reduce the mismatch of lattices exist. FIG. 18(b) schematically shows dislocation defects at the interface when a poly-crystalline MgO layer in which the (001) crystal plane had been preferentially oriented was stacked on a poly-crystalline Fe layer in which the (001) crystal plane had been preferentially oriented. At the interface, dislocation defects due to grain boundaries exist, together with dislocation defects that had been formed so as to reduce the mismatch of lattices.

### DESCRIPTION OF THE PREFERRED EMBODIMENTS

The term “ideal value” with regard to a single crystal herein refers to a value that has been estimated from ultraviolet photoemission spectroscopy experiments (see W. Wulfhekel, et al.: Appl. Phys. Lett. 78 (2001) 509.). The term “ideal value” is used herein because the aforementioned state can be considered to be an upper limit value of the potential barrier height of the tunnel barrier of an ideal single-crystalline MgO with almost no oxygen vacancy defects or lattice defects.

Before describing the preferred embodiments of the invention, an analysis conducted by the inventors is discussed. The magnetoresistance (MR) ratio of a MTJ device can be expressed by the following equation:
ΔR/Rp=(Rap−Rp)/Rp
where Rp and Rap indicate the tunnel junction resistance in the cases of parallel and antiparallel magnetization alignments, respectively, of two electrodes. The output voltage Vₒᵤₜ of an MTJ device is expressed by the following equation:
Vₒᵤₜ=V×(Rap−Rp)/Rap
where V is the bias voltage applied to the MTJ device. According to the Jullire's formula, the MR ratio at low bias voltage can be expressed by:
MR ratio=(Rap−Rp)/Rp=2P₁P₂/(1−P₁P₂), and
Pα=(Dα↑(E_{F})−Dα↓(E_{F}))/(Dα↑(E_{F})+Dα↓(E_{F}), where α=1, 2 (1)

In the above equations, Pα is the spin polarization of electrons, and Daα↑(E_{F}) and Dα↓(E_{F}) are the densities of state (DOS) at the Fermi energy (E_{F}) of the majority-spin band and the minority-spin band, respectively. Since the polarization of spin of ferromagnetic transition metals and alloys is approximately 0.5 or smaller, the Jullire's formula predicts the highest estimated MR ratio of 70%.

Although the MR ratio of approximately 70% has been obtained at room temperature when a MTJ device was made using an amorphous Al—O tunnel barrier and poly-crystalline electrodes, it has been difficult to obtain the output voltage of 200 mV, which is comparable to the output voltages of DRAMs. This difficulty poses a problem in realizing MRAMs, as discussed above.

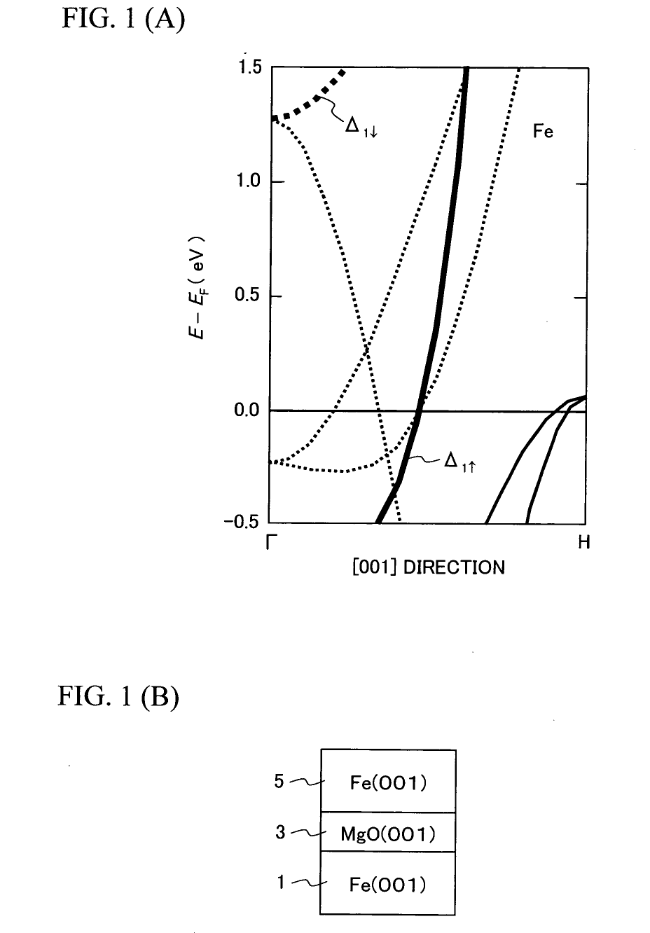

The inventors tried an approach to fabricate a MTJ device in which the tunnel barrier comprises a single-crystal of magnesium oxide (001) or a poly-crystalline MgO in which the (001) crystal plane is preferentially oriented. It is expected that, because magnesium oxide is a crystal (where the atoms are located in an orderly fashion) in contrast to the conventional amorphous alumina barrier, electrons are not scattered and the coherency of electrons' wave functions is conserved during the tunneling process. FIG. 1(B) shows the MTJ device structure according to an embodiment of the invention. FIG. 1(A) shows the energy band structure of the ferromagnetic Fe(001), that is, the E-E_{F} relationship with respect to the [100] direction of the wave-vector space. As shown in FIG. 1(B), the MTJ device structure of the present embodiment comprises a first Fe (001) layer 1, a second Fe (001) layer 5, and a single-crystalline MgOₓ (001) or a poly-crystalline MgOₓ (x<1) layer 3 sandwiched therebetween, the poly-crystalline layer having the (001) crystal plane preferentially oriented therein. According to the aforementioned Jullire's model, assuming that the momentum of conduction electrons is conserved in the tunneling process, the tunneling current that passes through MgO would be dominated by those electrons with wave vector k in the direction perpendicular to the tunnel barrier (i.e., normal to the junction interfaces).

In accordance with the energy band diagram shown in FIG. 1 (A) of Fe in the [100] (Γ-H) direction, the density of state (DOS) at the Fermi energy E_{F} does not exhibit a very high degree of spin polarization due to the fact that the sub-bands of the majority-spin and the minority-spin have states at the Fermi energy E_{F}. However, in case the coherency of electrons is conserved in the tunneling process, only those conduction electrons that have totally symmetrical wave functions with respect to the axis perpendicular to the barrier would couple with the states in the barrier region and come to have a certain tunneling probability. As shown in FIG. 1 (A), the majority-spin Δ₁ band (solid line) has states at the Fermi energy E_{F}, whereas the minority-spin Δ₁ band (broken line) does not have states at the Fermi energy E_{F}. Because of such half-metallic characteristics of the Fe-Δ₁ band, it can be expected that a very high MR ratio can be obtained in a coherent spin-polarized tunneling. Since the scattering of electrons is suppressed during the tunneling process in an epitaxial (single-crystal, or (001)-oriented poly-crystal) MTJ device, an epitaxial MTJ device is thought to be ideal for realizing the aforementioned coherent tunneling.

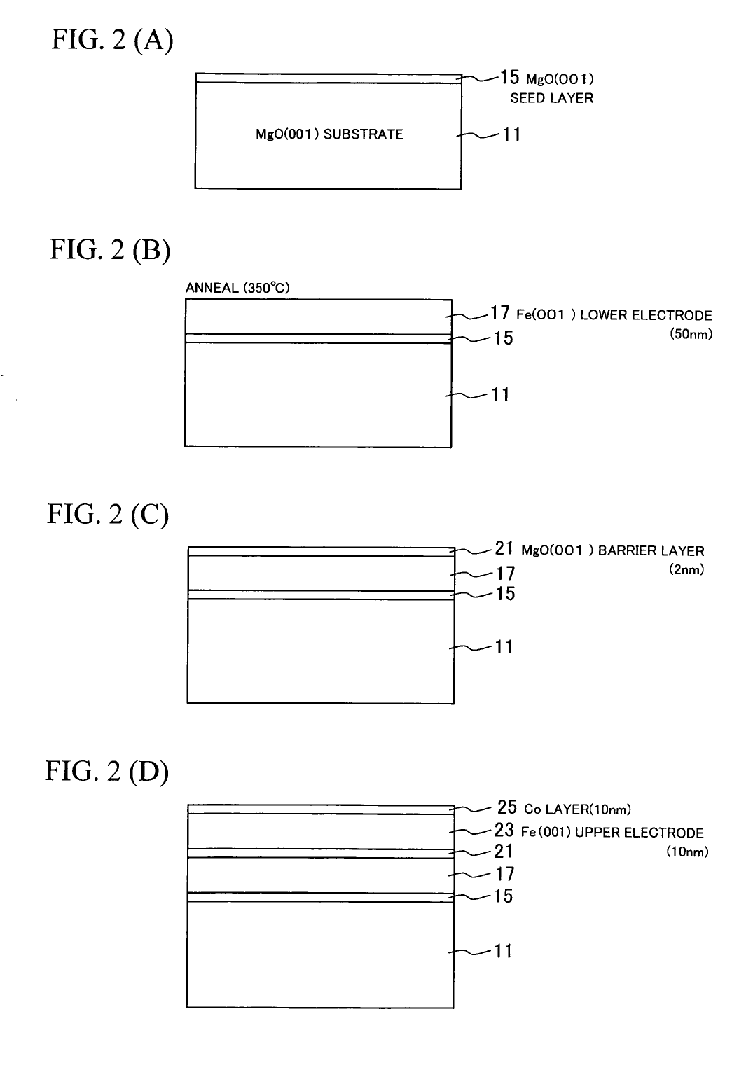

In the following, a MTJ device according to a first embodiment of the invention and a method of manufacturing the same will be described with reference to the drawings. FIGS. 2(A) to 2(D) schematically show the method of manufacturing the MTJ device having the Fe (001)/MgO(001)/Fe(001) structure according to the embodiment (to be hereafter referred to as a “Fe(001)/MgO(001)/Fe(001) MTJ device”). Fe(001) refers to a ferromagnetic material with the BCC structure. First, a single-crystalline MgO(001) substrate 11 is prepared. In order to improve the morphology of the surface of the single-crystalline MgO(001) substrate 11, a MgO(001) seed layer 15 is grown by the molecular beam epitaxy (MBE) method. This is followed by the growth of an epitaxial Fe(001) lower electrode (first electrode) 17 with a thickness of 50 nm on the MgO(001) seed layer 15 at room temperature, as shown in FIG. 1(B). Annealing is then performed at 350° C. under ultrahigh vacuum (2×10⁻⁸ Pa). The electron-beam evaporation conditions include an acceleration voltage of 8 kV, a growth rate of 0.02 nm/sec, and the growth temperature of room temperature (293K). The source is comprised of MgO of the stoichiometric composition (the ratio of Mg to O atoms being 1:1), the distance between the source and the substrate is 40 cm, the background vacuum pressure is 1×10⁻⁸ Pa, and the O₂ partial pressure is 1×10⁻⁶ Pa. Alternatively, a source with oxygen deficiency may be used instead of the MgO of the stoichiometric composition (the ratio of Mg to O atoms being 1:1).

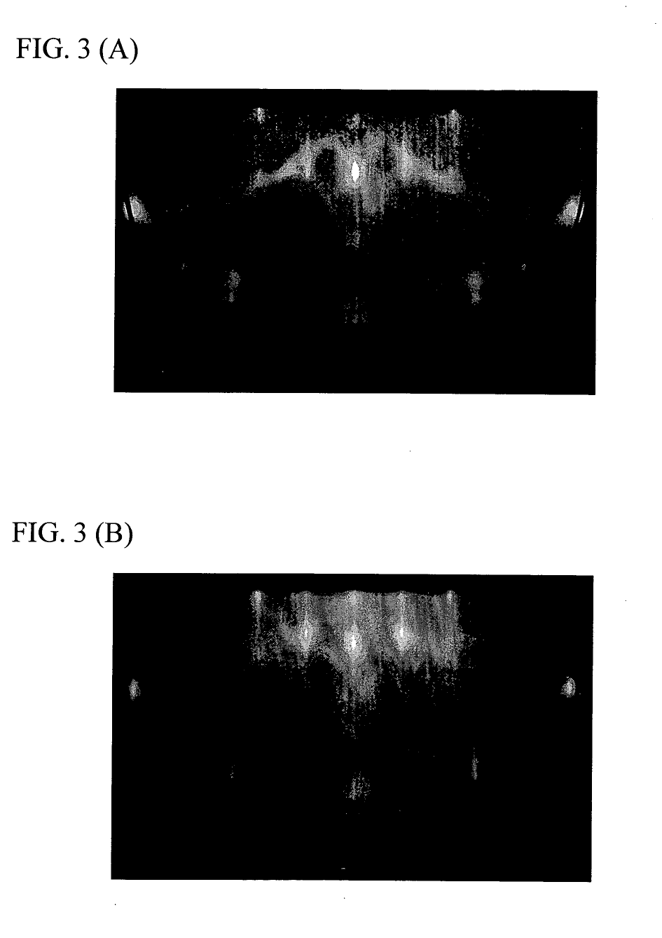

FIG. 3(a) shows a RHEED image of the Fe(001) lower electrode (first electrode) 17. As shown in FIG. 3(a), the Fe (001) lower electrode (first electrode) 17 possesses a good crystallinity and flatness. Thereafter, as shown in FIG. 2(C), a MgO(001) barrier layer 21 with a thickness of 2 nm was epitaxially grown on the Fe(001) lower electrode (first electrode) 17 at room temperature, also using the MgO electron beam evaporation process. FIG. 3(b) shows a RHEED image of the MgO(001) barrier layer 21. As shown in FIG. 3(b), the MgO(001) barrier layer 21 also possesses a good crystallinity and flatness.

As shown in FIG. 2(D), a Fe (001) upper electrode (second electrode) 23 with a thickness of 10 nm was formed on the MgO (001) barrier layer 21 at room temperature. In succession, a Co layer 25 with a thickness of 10 nm was then deposited on the Fe (001) upper electrode (second electrode) 23. The Co layer 25 was provided so as to realize an antiparallel magnetization alignment by giving a high coercive field to the upper electrode 23. Thereafter, the above-prepared sample was subjected to microfabrication so as to obtain a Fe (001)/MgO (001)/Fe (001) MTJ device.

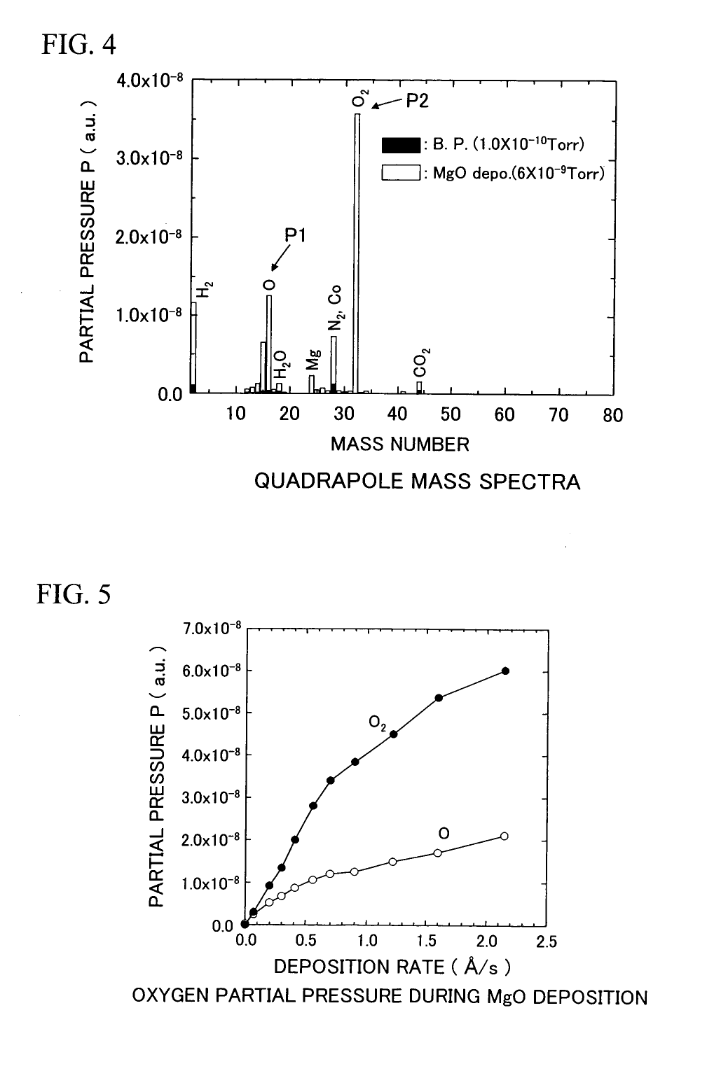

The aforementioned MgO evaporation using an electron beam was performed under ultrahigh vacuum of 10⁻⁹ Torr. It can be seen that in this method, a colorless, transparent and good thin film can be formed even when the film is formed on a glass substrate to the thickness of 300 nm. FIG. 4 shows the results of observation of the quadrupole mass spectrum during MgO growth. As shown in FIG. 4, it can be seen that the partial pressures regarding the spectrum P1 of O and the spectrum P2 of O₂ are high. FIG. 5 shows the film deposition-rate dependence of oxygen partial pressure during MgO evaporation. As shown in FIG. 5, it can be seen that oxygen partial pressure itself is rather high and that it increases with the deposition rate. These suggest the decomposition of oxygen from MgO during the deposition of MgO, indicating the possibility of oxygen deficiency, such as in MgOₓ (0.9<x<1). If there is oxygen deficiency, the MgO tunnel barrier height could presumably be lowered (to within a range of 0.10 to 0.85 eV, or, more specifically, a range of 0.2 to 0.5 eV), which would result in an increase in tunneling current. In the case of a usual Al—O tunnel barrier, the tunnel barrier height with respect to Fe (001) electrodes is known to be from 0.7 to 2.5 eV. Meanwhile, an ideal tunnel barrier height for the MgO crystal is 3.6 eV, and experimental values of 0.9 to 3.7 eV have been obtained. When the method of the present embodiment is used, a tunnel barrier height of approximately 0.3 eV is estimated, which indicates that the resistance of the magnetic tunnel junction device can be reduced. However, the low barrier height can also be related to other factors, such as the aforementioned influence of coherent tunneling.

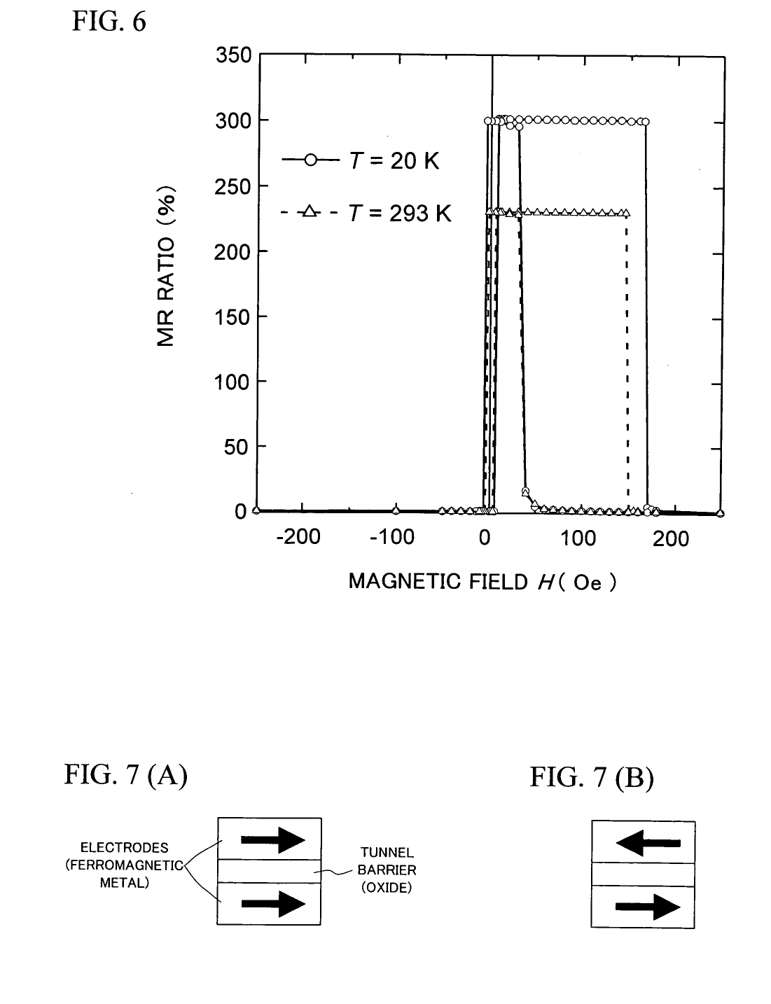

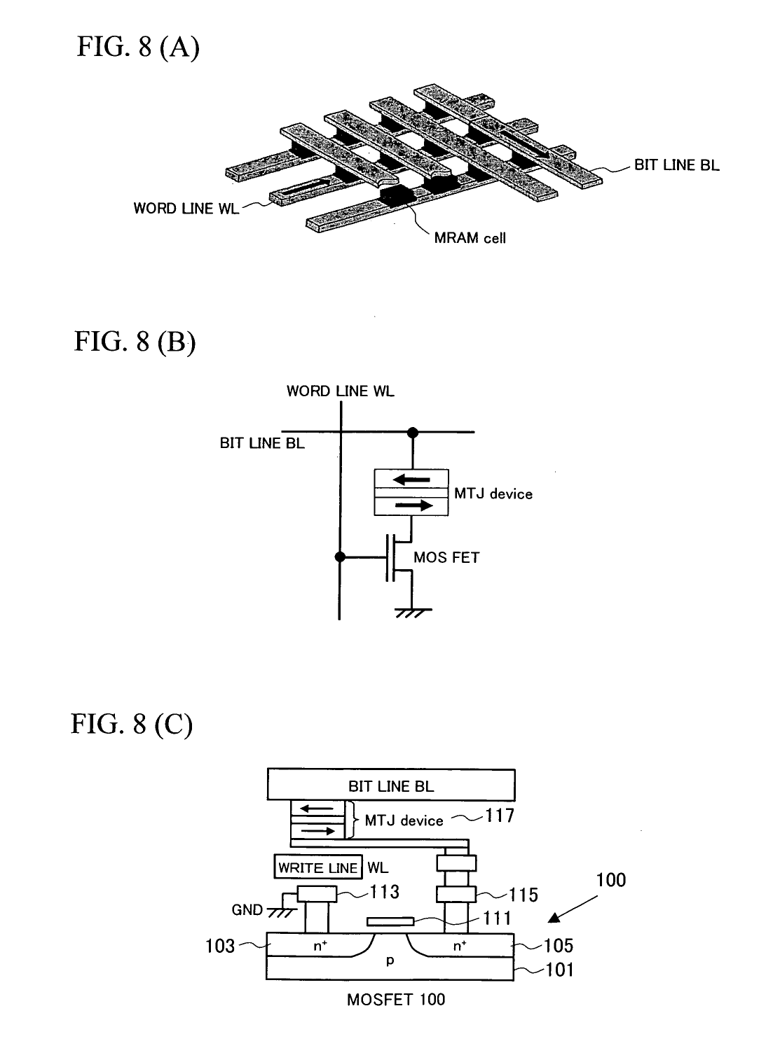

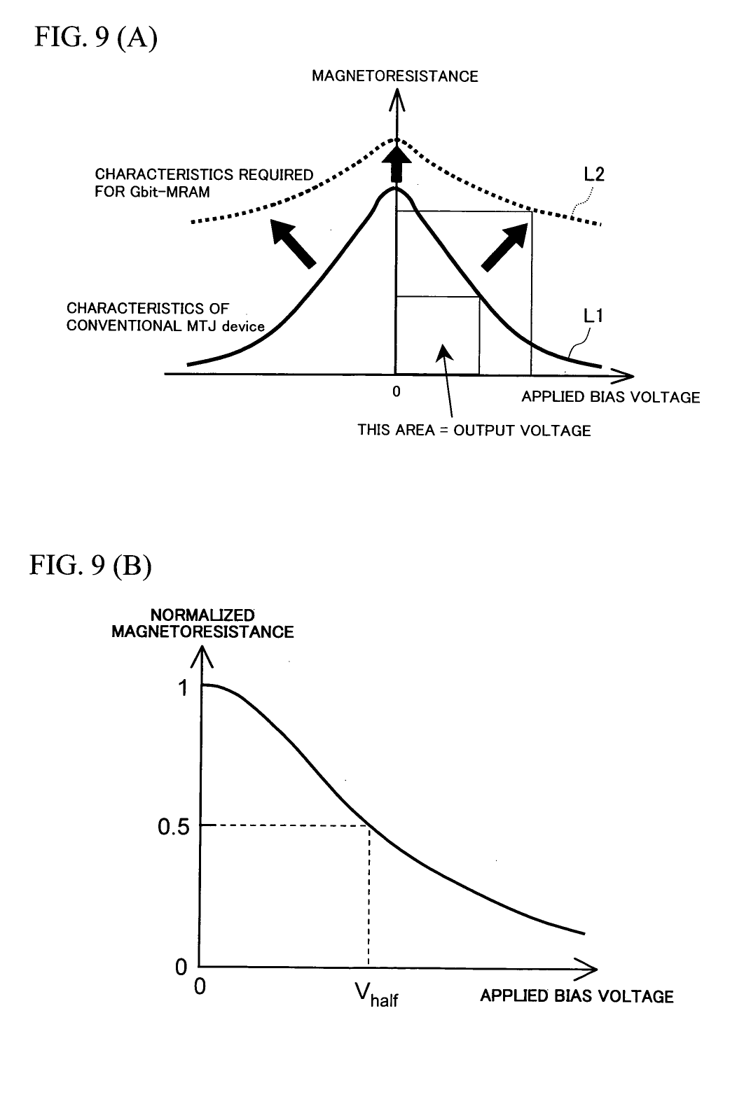

FIG. 6 shows a typical magnetoresistance curve of the Fe (001)/MgO (001)/Fe (001) MTJ device manufactured by the above-described method. At a measurement temperature of 20K, the MR ratio was 300%, while at a measurement temperature of 293K, the MR ratio was 230%. These values represent the highest MR ratios that have so far been achieved at room temperature. Such high MR ratios cannot be accounted for by the spin polarization of the Fe (001) electrode, and they are rather believed to be related to a coherent spin polarization tunneling. In 160 MTJ devices that were manufactured by way of trial, variations with regard to MR ratio and tunneling resistance value were not more than 5%. The yield of the MTJ devices was 95% or higher at the laboratory stage. Such high values suggest the validity of the approach of the invention. The resistance-area product (RA) of the MTJ devices was 500 Ωμm , which is a value suitable for MRAMs.

Although Fe (001) of the BCC structure has been used in the above embodiment, Fe alloys of BCC, such as Fe—Co alloy, Fe—Ni alloy, or Fe—Pt alloy, for example, may be used instead. Alternatively, Co or Ni layers with a thickness of one or several atoms may be disposed between the electrode layer and the MgO (001) barrier layer.

Hereafter, a magnetic tunnel junction device according to a second embodiment of the invention and a method of manufacturing the same will be described. In the method of manufacturing a the Fe (001)/MgO (001)/Fe (001) MTJ device according to the present embodiment, MgO(001) is initially deposited in a poly-crystalline or amorphous state by sputtering or the like, and then an annealing process is performed such that a polycrystal in which the (001) crystal plane is oriented or a single crystal is obtained. The sputtering conditions were such that, for example, the temperature was room temperature (293K), a 2-inch φ MgO was used as a target, and sputtering was conducted in an Ar atmosphere. The acceleration power was 200 W and the growth rate was 0.008 nm/s. Because MgO deposited under these conditions is in an amorphous state, a crystallized MgO can be obtained by increasing the annealing temperature to 300° C. from room temperature and maintaining that temperature for a certain duration of time.

An oxygen deficiency may be introduced by a method whereby an oxygen deficiency is produced during growth, a method whereby an oxygen deficiency is introduced subsequently, or a method whereby a state with an oxygen deficiency is subjected to an oxygen plasma process or natural oxidation so as to achieve a certain oxygen deficiency level.

As described above, in accordance with the magnetic tunnel junction device technology of the present embodiment, an annealing process is carried out for crystallization after an amorphous MgO has been deposited by sputtering, thereby eliminating the need for large-sized or elaborate equipment.

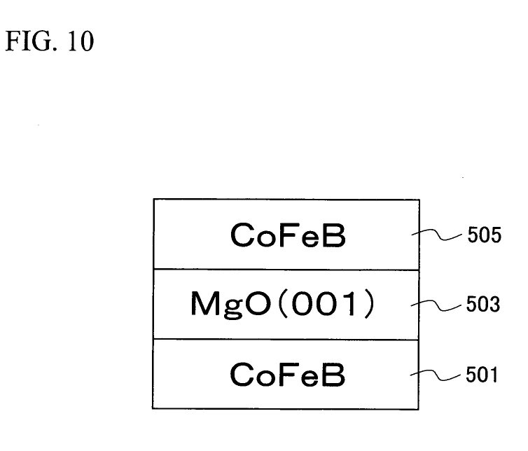

Hereafter, a MTJ device according to a variation of the foregoing embodiment of the invention will be described with reference to the drawings. FIG. 10 shows the structure of the MTJ device of the variation, the figure corresponding to FIG. 1(B). As shown in FIG. 10, the MTJ device of the variation is characterized in that, as in the MTJ device of the foregoing embodiment, a single-crystalline MgOₓ (001) or an oxygen-deficient poly-crystalline MgOₓ (x<1) layer 503 in which the (001) crystal plane is preferentially oriented is disposed between electrodes that are comprised of layers of amorphous ferromagnetic alloy, such as CoFeB layers 501 and 505, for example. Amorphous ferromagnetic alloy can be formed by evaporation or sputtering. Resultant characteristics were substantially identical to those obtained in the first embodiment.

Other examples of amorphous ferromagnetic alloy that can be used include FeCoB, FeCoBSi, FeCoBP, FeZr and CoZr.

Hereafter, a MTJ device according to a third embodiment of the invention will be described with reference to the drawings.

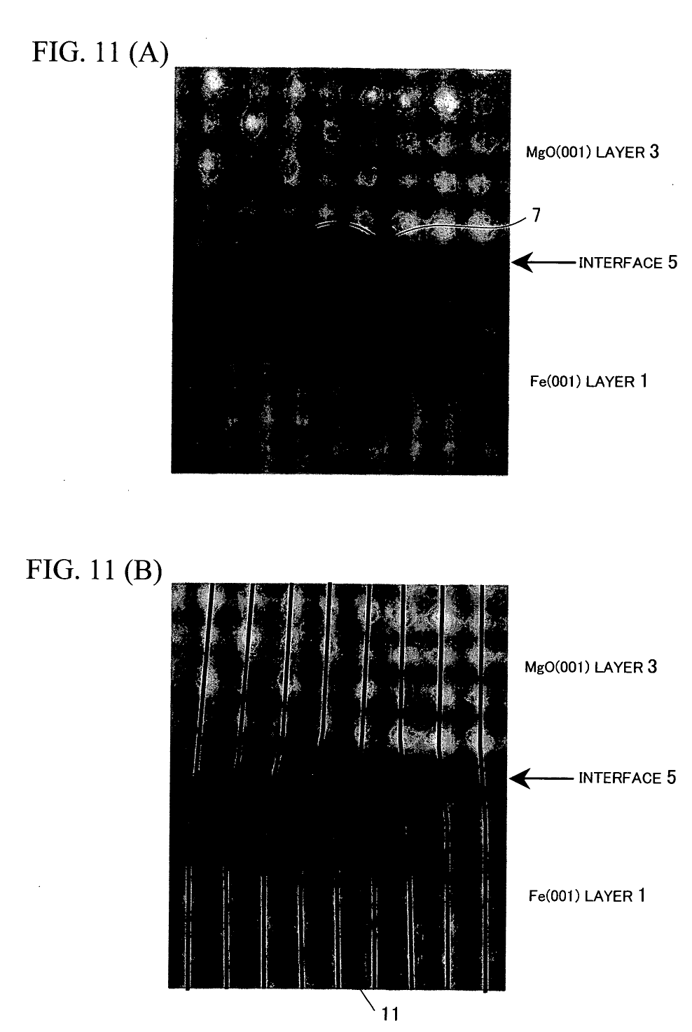

As already described above, output voltage can be increased by improving the bias voltage dependence or V_{half} of the MTJ device. In order to increase the V_{half} value of a MTJ device having an MgO (001) tunneling barrier, it is effective to lower the density of dislocation defects that exist at the interface between the MgO (001) tunnel barrier layer and the ferromagnetic metal electrode layer. FIG. 11(a) and (b) show cross-sectional transmission electron microscope images of the interface between a single-crystalline Fe (001) electrode layer and a single-crystalline MgO (001) tunnel barrier layer. In these images, dislocation defects can be observed at the interface. Such dislocation defects at the interface inevitably exist to a greater or smaller degree when the lattice constants (interatomic spacings) of the two layers are different. In the case of the interface between the Fe (001) layer and the MgO (001) layer, the difference in interatomic spacings in the plane is as much as about 3.6% (as compared in bulk values). Therefore, dislocation defects of high density tend to be formed at the interface of such layers.

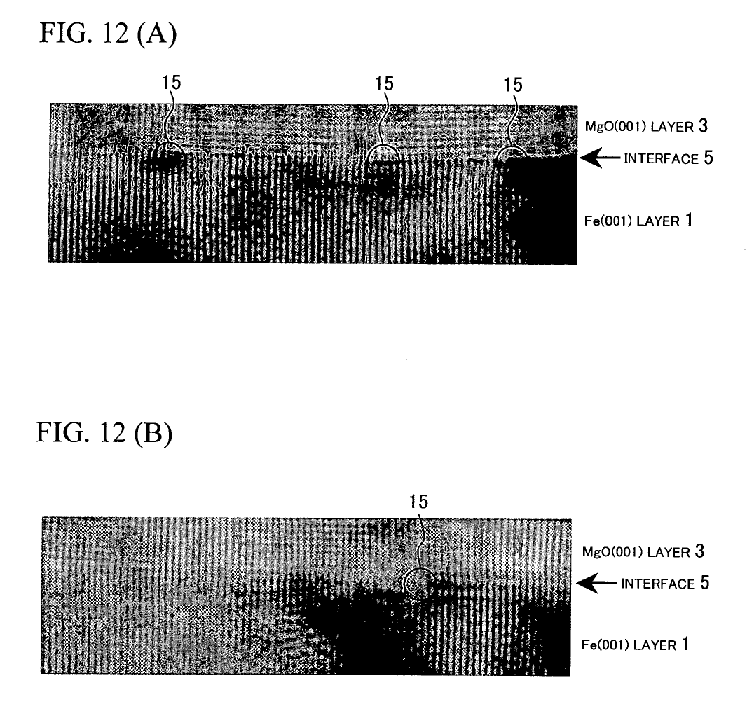

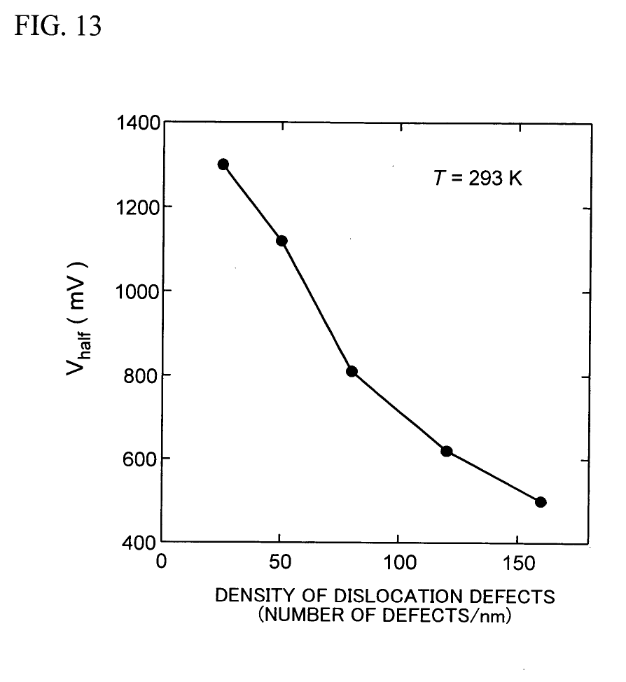

The inventors realized that the density of dislocation defects at the interface -can be controlled by varying film-deposition conditions. For example, the dislocation defect density at the interface can be changed by depositing the MgO (001) tunnel barrier layer on the Fe (001) electrode layer by electron-beam deposition with different substrate temperatures, different growth rates, or different levels of vacuum. When the MgO layer is deposited in a ultrahigh vacuum at the rate of 0.08 nm/s (see FIG. 12(a)), the dislocation defect density at the interface is on the order of 100 defects/μm. When the MgO layer is deposited in a ultrahigh vacuum at the substrate temperature of 100° C. and at the rate of 0.002 nm/s (see FIG. 13(b)), the dislocation defect density at the interface decreases to approximately 25 defects/μm.

FIG. 13 shows the relationship between the dislocation defect density at the interface and the V_{half} value of the MTJ device measured at 293K. As shown in FIG. 13, as the dislocation defect density at the interface decreases, the bias voltage dependence of magnetoresistance is improved. Particularly, V_{half} starts to increase sharply at the dislocation defect density of approximately 50 to 75 defects/μm, and it reaches 1300 mV at the dislocation defect density of 25 defects/μm.

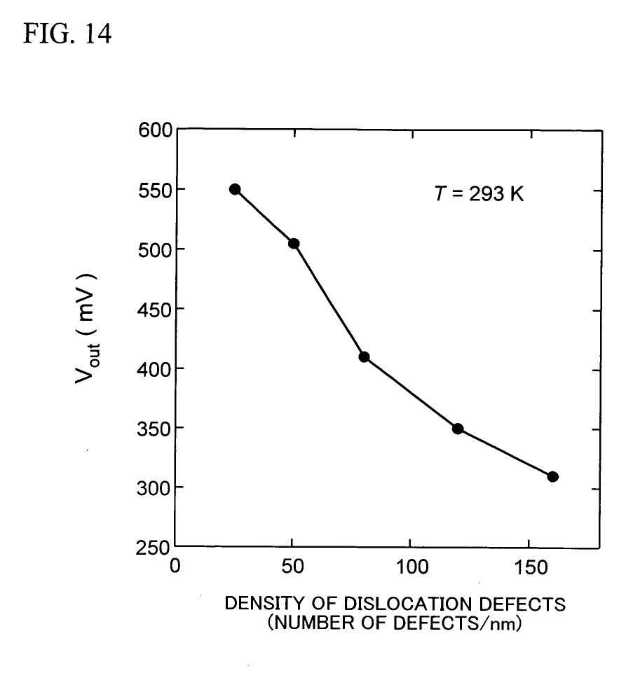

FIG. 14 shows the relationship between the dislocation defect density at the interface and the maximum output voltage Vₒᵤₜ, of the MTJ device. As will be seen from FIG. 14, by lowering the dislocation defect density so as to increase the bias voltage dependence of magnetoresistance, the output voltage of the MTJ device can be increased.

Such improvement in bias dependence that is achieved by reducing the dislocation defect density at interface can be explained by a mechanism by which the spin scattering of tunneling electrons by magnons at the interface between ferromagnetic electrode layers (see a non-patent document J. Murai et al., Jpn. J. Appl. Phys. Vol. 38, pp. L1106 (1999)) is reinforced by the dislocation defects at the interface.

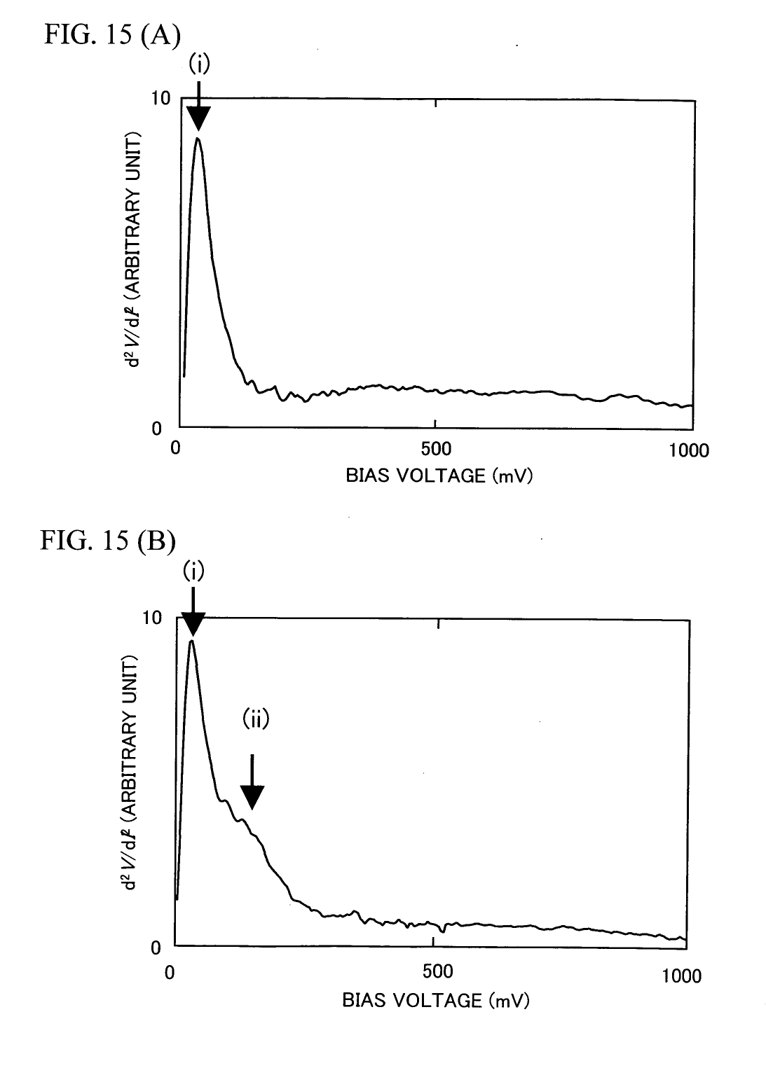

FIG. 15(A) shows the second-derivative conductance spectrum (bias-voltage dependence of d²V/dI²) in an antiparallel magnetization alignment of a MTJ device having a dislocation defect density of 25 defects/μm at the interface between the Fe (001) layer and the MgO (001) layer. FIG. 15(B) shows the second-derivative conductance spectrum (bias-voltage dependence of d²V/dI²) in an antiparallel magnetization alignment of a MTJ device having a dislocation defect density of 100 defects/μm at the interface between the Fe (001) layer and the MgO (001) layer. Such a presence or absence of spin scatterings by magnons can be verified by measuring the second-derivative conductance spectrum (bias-voltage dependence of d²V/dI²). When the magnetization is antiparallel, tunneling current increases if the spin of tunneling electrons is scattered by magnons, whereby the second-derivative conductivity (d²V/dI²) increases. As a result, peak structures appear in the second-derivative conduction spectrum.

As shown in FIG. 15(A) and (B), in the second-derivative conductance spectra of two kinds of MTJ devices having different dislocation defect densities in an antiparallel magnetization alignment, a peak structure ((i) in the figure) was observed at a bias voltage of approximately 50 mV when the dislocation defect density was small at 25 defects/μt (see FIG. 15(A)). This peak structure (i) is due to the usual spin scattering caused by magnons. On the other hand, when the dislocation defect density was high at 100 defects/μm (see FIG. 15(B)), a second peak structure (ii) was observed at a bias voltage of approximately 150 mV in addition to the first peak structure (i) at the bias voltage of approximately 50 mV. This second peak (ii) at 150 mV is due to the spin scattering caused by magnons that had been reinforced by dislocation defects at the interface. Such a scattering mechanism adversely affects the bias voltage dependence of the MTJ device.

The aforementioned spin scattering of tunneling electrons caused by magnons occurs at the interface downstream of the flow of tunneling electrons, namely, at the interface towards the electrode layer to which a positive bias voltage is applied. Therefore, the dislocation defect density at the interface on the side where a positive bias voltage is applied greatly affects the bias voltage dependence of the MTJ device. Conversely, the dislocation defect density on the side of the interface where a negative bias voltage is applied hardly affects the bias voltage dependence of the MTJ device. Thus, in order to improve the bias dependence, it is important to reduce the dislocation defect density at the interface downstream of the flow of tunneling electron, namely, on the side of the interface where a positive bias voltage is applied.

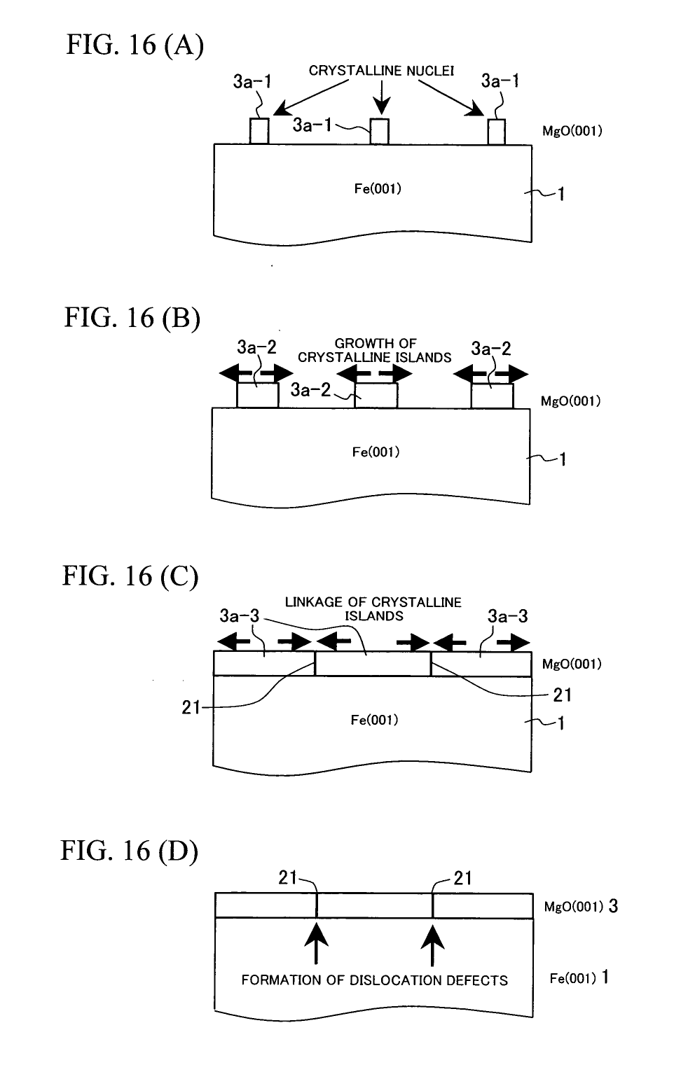

A method for reducing the dislocation defect density at the interface between the Fe (001) electrode layer and the MgO (001) tunnel barrier layer grown thereon will be described in the following. It is believed that the mechanism by which dislocation defects develops at the interface is related to the density with which nuclei develop in the initial phase of growth, as will be described later. FIG. 16 shows a mode in which crystals grow when the MgO (001) layer is stacked on the Fe (001) layer. As shown in FIG. 16, when the MgO (001) layer is stacked on the Fe (001) electrode layer, minute crystalline nuclei of MgO (001) with a thickness of a single atomic layer develop in the initial phase of crystal growth (FIG. 16(a)). Each of the crystal nuclei grows in the direction of the plane, thereby forming minute crystalline islands (FIG. 16(b)). While the in-plane interatomic spacing in the Fe (001) electrode layer is greater than that in the MgO (001) tunnel barrier layer, the in-plane interatomic spacing of the MgO (001) layer extends such that the spacing is matched with the lattice of the Fe (001) electrode layer is achieved. Namely, the lattice of the MgO layer becomes deformed. As the MgO (001) layer further grows, the minute crystalline islands of MgO (001) become linked to one another, whereby a continuous MgO (001) layer with a thickness of a single atomic layer is formed (FIG. 16(c)). At the same time, dislocation defects are formed where the crystalline islands came into contact with one another, thereby reducing the crystalline deformation in the MgO (001) layer (FIG. 16(d)).

Thus, the density of dislocation defects at the interface is associated with (or substantially identical to) the density (to be hereafter referred to as “the nucleus development density”) with which crystalline nuclei develop in the initial phase of the growth of the MgO (001) layer. Therefore, by controlling the nucleus development density, the dislocation defect density at the interface can be controlled. Furthermore, because a similar phenomenon also occurs when the Fe (001) layer is grown on the MgO (001) layer, the dislocation defect density at the interface is associated with (or substantially identical to) the nucleus development density in the initial phase of the growth of the Fe (001) layer.

The nucleus development density depends sensitively on the thin-film growth conditions. For example, the nucleus development density can be decreased by either decreasing the film-deposition rate or by increasing the substrate temperature during film deposition. Alternatively, the nucleus development density can also be decreased by making the underlayer flat on an atomic level.

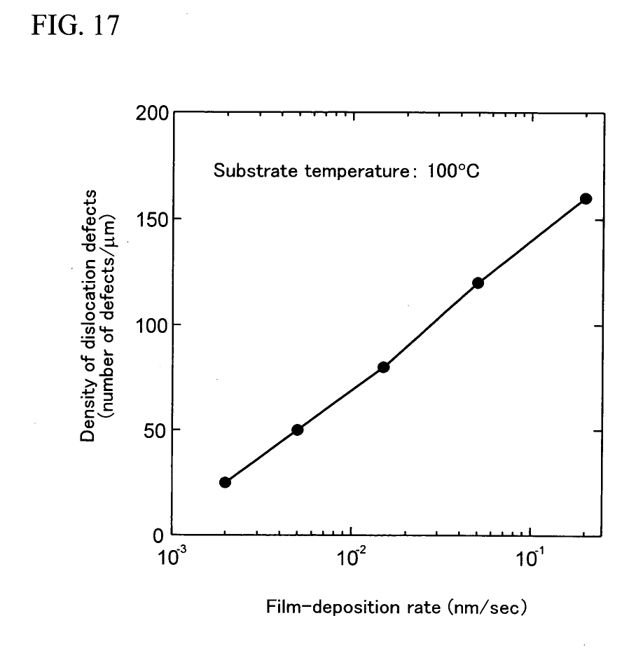

FIG. 17 shows an example of how the dislocation defect density at the interface can be varied by depositing the MgO (001) layer on the Fe (001) layer at various rates when the substrate temperature is maintained constant (100° C.) during film deposition. In this example, the underlayer was comprised of a Fe (001) layer with a surface that was flat on an atomic level, namely, with a surface atomic-step density of 10 defects/μm or smaller. It can be seen that, by thus reducing the rate of film deposition, the dislocation defect density at the interface can be greatly changed even at the same substrate temperature. For example, under the conditions shown in FIG. 17, it is possible to achieve a dislocation defect density of 50 defects/μm by setting the film-deposition rate at 5×10⁻³, or to achieve a dislocation defect density of 25 defects/μm by setting the film-deposition rate at 2×10⁻³. It is also possible to reduce the dislocation defect density by increasing the substrate temperature during film deposition.

It is noted, however, that the nucleus development density in the initial phase of growth is determined by a complex combination of various factors including the film-deposition rate, substrate temperature, the diffusion coefficient of atoms, the atomic composition of the ferromagnetic electrode layers, and the surface condition of the underlayer. The nucleus development density is therefore not limited by the aforementioned film-deposition conditions alone; and yet it can be reduced by decreasing the film-deposition rate if the other conditions are the same.

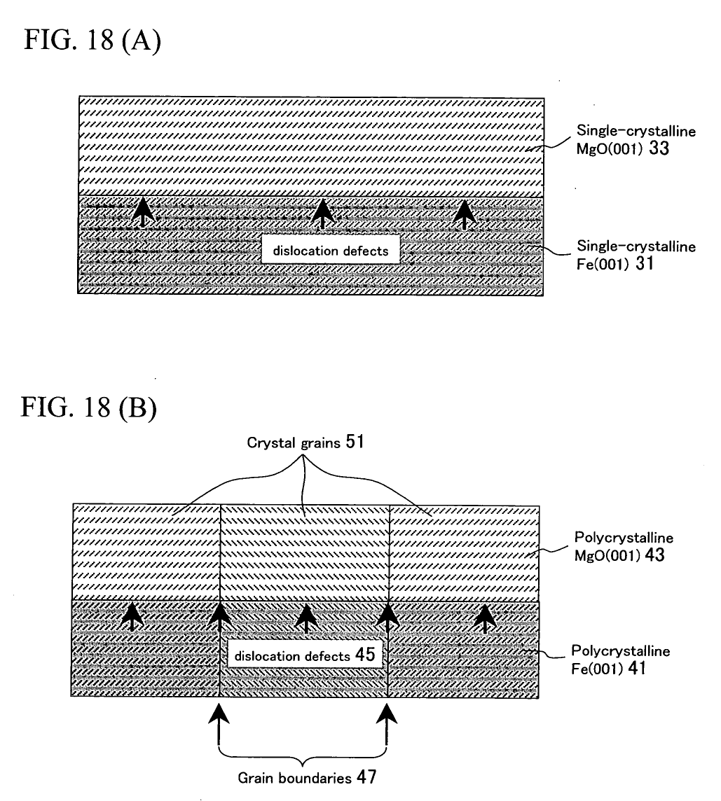

As shown in FIG. 18, when the ferromagnetic electrode layer and the MgO tunnel barrier layer of which a MTJ device is comprised are polycrystals in which the (001) crystalline plane is preferentially oriented, dislocation defects exist that are due to the grain boundary of the electrode layers and the tunnel barrier layer, in addition to the dislocation defects that are produced for relaxing the aforementioned lattice mismatch. Specifically, the dislocation defect density at the interface would be the sum of the dislocation defect density due to grain boundaries and the dislocation defect density within the crystal grains. Further, when the ferromagnetic electrode layers of the MTJ device are amorphous structures and when the MgO tunnel barrier layer is a polycrystal in which the (001) crystal plane is preferentially oriented, the dislocation defect density at the interface would be equal to the dislocation defect density due to the grain boundaries of the MgO tunnel barrier layer.

While the MTJ device of the invention has been described with reference to preferred embodiments, the invention is not limited by those embodiments, and it should be obvious to those skilled in the art that various changes, improvements, or combinations may be made to the invention. For example, the height of the tunnel barrier may be adjusted by doping Ca or Sr, instead of introducing an oxygen deficiency to the MgO layer. Further, while the MgO layer has been described to be deposited by electron beam deposition or sputtering, it should be obvious that other deposition methods are also possible. The term “high vacuum” refers to values on the order of no more than 10⁻⁶ Pa in the case where oxygen is not introduced, for example. In the case where oxygen is intentionally introduced, the term refers to values on the order of 10⁻⁴ Pa.

In accordance with the invention, the output voltage values of MRAMs can be increased, and a structure suitable for ultra-highly integrated MRAMs of gigabit-class can be obtained. As a result, practical application of MRAMs becomes possible.

What is claimed is:

1. A magnetic tunnel junction device of a magnetic tunnel junction structure comprising:
a tunnel barrier layer;
a first single-crystalline ferromagnetic material layer of the BCC structure formed on a first plane of said tunnel barrier layer; and
a second single-crystalline ferromagnetic material layer of the BCC structure formed on a second plane of said tunnel barrier layer;
wherein said tunnel barrier layer is formed of a single-crystalline MgO (001) or a single-crystalline MgOₓ (001) (x<1) layer (to be hereafter referred to as “a single-crystalline MgO (001)”),
and wherein the density of dislocation defects that exist at the interface between one of said first or said second ferromagnetic layers and said tunnel barrier layer is not more than 50 defects/μm.

2. A magnetic tunnel junction device of a magnetic tunnel junction structure comprising:
a tunnel barrier layer;
a first single-crystalline ferromagnetic material layer of the BCC structure formed on a first plane of said tunnel barrier layer; and
a second single-crystalline ferromagnetic material layer of the BCC structure formed on a second plane of said tunnel barrier layer;
wherein said tunnel barrier layer is formed of a single-crystalline MgO (001) or a single-crystalline MgOₓ (001) (x<1) layer (to be hereafter referred to as “a single-crystalline MgO (001)”),
and wherein the density of dislocation defects that exist at the interface between one of said first or said second ferromagnetic layers and said tunnel barrier layer is not more than 25 defects/μm.

3. A magnetic tunnel junction device of a magnetic tunnel junction structure comprising:
a tunnel barrier layer;
a first single-crystalline ferromagnetic material layer of the BCC structure formed on a first plane of said tunnel barrier layer; and
a second single-crystalline ferromagnetic material layer of the BCC structure formed on a second plane of said tunnel barrier layer;
wherein said tunnel barrier layer is formed of a single-crystalline MgO (001) or a single-crystalline MgOₓ (001) (x<1) layer (to be hereafter referred to as “a single-crystalline MgO (001)”),
and wherein the density of dislocation defects that exist at the interface between one of said first or said second ferromagnetic layers and said tunnel barrier layer is not more than the density at which the spin scattering of tunneling electrons caused by magnons at the interface between the ferromagnetic electrode layers is suppressed.

4. A magnetic tunnel junction device comprising:
a tunnel barrier layer comprising a single-crystalline MgO (001);
a first single-crystalline ferromagnetic material layer of the BCC structure formed on a first plane of said tunnel barrier layer; and
a second single-crystalline ferromagnetic material layer of the BCC structure formed on a second plane of said tunnel barrier layer, wherein the density of dislocation defects that exist at the interface between one of said first or said second ferromagnetic material layers to which a positive bias voltage is applied during operation and said tunnel barrier layer is not more than 50 defects/μm.

5. A magnetic tunnel junction device comprising:
a tunnel barrier layer comprising a single-crystalline MgO (001);
a first single-crystalline ferromagnetic material layer comprising an alloy of the BCC structure formed on a first plane of said tunnel barrier layer and including Fe or Co as a principal component; and
a second single-crystalline ferromagnetic material layer comprising an alloy of the BCC structure including Fe or Co as a principal component, said alloy being formed on a second plane of said tunnel barrier layer,
wherein the density of dislocation defects that exist at the interface between one of said first or said second ferromagnetic material layers and said tunnel barrier layer is not more than 50 defects/μm.

6. A magnetic tunnel junction device comprising:
a tunnel barrier layer comprising a single-crystalline MgO (001);
a first single-crystalline ferromagnetic material layer comprising an alloy of the BCC structure formed on a first plane of said tunnel barrier layer and including Fe or Co as a principal component; and
a second single-crystalline ferromagnetic material layer comprising an alloy of the BCC structure including Fe or Co as a principal component, said alloy being formed on a second plane of said tunnel barrier layer,
wherein the density of dislocation defects that exist at the interface between one of said first or said second ferromagnetic material layers to which a positive bias voltage is applied during operation and said tunnel barrier layer is not more than 50 defects/μm.

7. A magnetic tunnel junction device comprising:
a tunnel barrier layer comprising a single-crystalline MgO (001);
a first single-crystalline Fe (001) layer formed on a first plane of said tunnel barrier layer; and
a second single-crystalline Fe (001) layer formed on a second plane of said tunnel barrier layer,
wherein the density of dislocation defects that exist at the interface between one of said first or said second ferromagnetic material layers and said tunnel barrier layer is not more than 50 defects/μm.

8. A magnetic tunnel junction device comprising:
a tunnel barrier layer comprising a single-crystalline MgO (001);
a first single-crystalline Fe (001) layer formed on a first plane of said tunnel barrier layer; and
a second single-crystalline Fe (001) layer formed on a second plane of said tunnel barrier layer,
wherein the density of dislocation defects that exist at the interface between one of said first or said second ferromagnetic material layers to which a positive bias voltage is applied during operation and said tunnel barrier layer is not more than 50 defects/μm.

9. The magnetic tunnel junction device according to claim 1, wherein the density of dislocation defects that exist at the interface between one of said first or said second ferromagnetic material layers to which a positive bias voltage is applied during operation and said tunnel barrier layer is smaller than the density of dislocation defects that exist at the interface between the ferromagnetic material layer to which a negative bias voltage is applied and said tunnel barrier layer.

10. A magnetic tunnel junction device of a magnetic tunnel junction structure comprising:
a tunnel barrier layer;
a first poly-crystalline ferromagnetic material layer of the BCC structure that is formed on a first plane of said tunnel barrier layer and in which the (001) crystal plane is preferentially oriented; and
a second poly-crystalline ferromagnetic material layer of the BCC structure that is formed on a second plane of said tunnel barrier layer and in which the (001) crystal plane is preferentially oriented;
wherein said tunnel barrier layer is formed of a poly-crystalline MgO (001) in which the (001) crystal plane is preferentially oriented, or of a poly-crystalline MgOₓ (x<1) layer (to be hereafter referred to as “a poly-crystalline MgO (001)”) in which the (001) crystal plane is preferentially oriented,
and wherein the sum of the density of dislocation defects caused by grain boundaries and the density of dislocation defects within crystal grains (said sum being referred to as “the dislocation defects” in the subsequent claims), said dislocation defects being present in the interface between one of said first or said second ferromagnetic material layers and said tunnel barrier layer, is not more than 50 defects/μm.

11. A magnetic tunnel junction device comprising:
a poly-crystalline MgO (001) tunnel barrier layer;
a first poly-crystalline ferromagnetic material layer of the BCC structure that is formed on a first plane of said tunnel barrier layer and in which the (001) crystal plane is preferentially oriented; and
a second poly-crystalline ferromagnetic material layer of the BCC structure that is formed on a second plane of said tunnel barrier layer and in which the (001) crystal plane is preferentially oriented;
wherein the density of dislocation defects that exist at the interface between one of said first or said second ferromagnetic material layers to which a positive bias voltage is applied during operation and said tunnel barrier layer is not more than 50 defects/μm.

12. A magnetic tunnel junction device comprising:
a poly-crystalline MgO (001) tunnel barrier layer;
a first single-crystalline ferromagnetic material layer comprising an alloy of the BCC structure formed on a first plane of said tunnel barrier layer and including Fe or Co as a principal component; and
a second single-crystalline ferromagnetic material layer comprising an alloy of the BCC structure including Fe or Co as a principal component, said alloy being formed on a second plane of said tunnel barrier layer,
wherein the density of dislocation defects that exist at the interface between one of said first or said second ferromagnetic material layers and said tunnel barrier layer is not more than 50 defects/μm.

13. A magnetic tunnel junction device comprising:
a poly-crystalline MgO (001) tunnel barrier layer;
a first single-crystalline ferromagnetic material layer comprising an alloy of the BCC structure formed on a first plane of said tunnel barrier layer and including Fe or Co as a principal component; and
a second single-crystalline ferromagnetic material layer comprising an alloy of the BCC structure including Fe or Co as a principal component, said alloy being formed on a second plane of said tunnel barrier layer,
wherein the density of dislocation defects that exist at the interface between one of said first or said second ferromagnetic material layers to which a positive bias voltage is applied during operation and said tunnel barrier layer is not more than 50 defects/μm.

14. A magnetic tunnel junction device comprising:
a poly-crystalline MgO (001) tunnel barrier layer;
a first poly-crystalline Fe layer that is formed on a first plane of said tunnel barrier layer and in which the (001) crystal plane is preferentially oriented; and
a second poly-crystalline Fe layer that is formed on a second plane of said tunnel barrier layer and in which the (001) crystal plane is preferentially oriented,
wherein the density of dislocation defects that exist at the interface between one of said first or said second ferromagnetic material layers and said tunnel barrier layer is not more than 50 defects/μm.

15. A magnetic tunnel junction device comprising:
a poly-crystalline MgO (001) tunnel barrier layer;
a first poly-crystalline Fe layer that is formed on a first plane of said tunnel barrier layer and in which the (001) crystal plane is preferentially oriented; and
a second poly-crystalline Fe layer that is formed on a second plane of said tunnel barrier layer and in which the (001) crystal plane is preferentially oriented,
wherein the density of dislocation defects that exist at the interface between one of said first or said second ferromagnetic material layers to which a positive bias voltage is applied during operation and said tunnel barrier layer is not more than 50 defects/μm.

16. A magnetic tunnel junction device comprising:
a poly-crystalline MgO (001) tunnel barrier layer;
a first ferromagnetic material layer formed on a first plane of said tunnel barrier layer and comprising an amorphous alloy including Fe or Co as a principal component; and
a second ferromagnetic material layer formed on a second plane of said tunnel barrier layer and comprising an amorphous alloy including Fe or Co as a principal component,
wherein the density of dislocation defects that exist at the interface between one of said first or said second ferromagnetic material layers and said tunnel barrier layer is not more than 50 defects/μm.

17. A magnetic tunnel junction device comprising:
a poly-crystalline MgO (001) tunnel barrier layer;
a first ferromagnetic material layer formed on a first plane of said tunnel barrier layer and comprising an amorphous alloy including Fe or Co as a principal component; and
a second ferromagnetic material layer formed on a second plane of said tunnel barrier layer and comprising an amorphous alloy including Fe or Co as a principal component,
wherein the density of dislocation defects that exist at the interface between one of said first or said second ferromagnetic material layers to which a positive bias voltage is applied during operation and said tunnel barrier layer and that is due to grain boundaries of the poly-crystalline MgO is not more than 50 defects/μm.

18. The magnetic tunnel junction device according to any one of claims 10 to 17, wherein the density of dislocation defects that exist at the interface between one of said first or said second ferromagnetic material layers to which a positive bias voltage is applied during operation and said tunnel barrier layer is smaller than the density of dislocation defects that exist at the interface between the ferromagnetic material layer to which a negative bias voltage is applied and said tunnel barrier layer.

19. A memory device comprising:
a single transistor; and
the magnetic tunnel junction device according to any one of claims 1 to 3, wherein said magnetic tunnel junction device is used as a load of said transistor.

20. A memory device comprising the magnetic tunnel junction device according to claim 1.

21. A magnetic sensor comprising the magnetic tunnel junction device according to claim 1.

22. A method of manufacturing a magnetic tunnel junction device comprising:
a tunnel barrier layer comprising a single-crystalline MgO (001);
a first single-crystalline ferromagnetic material layer comprising an alloy of the BCC structure formed on a first plane of said tunnel barrier layer and including Fe or Co as a principal component; and
a second single-crystalline ferromagnetic material layer comprising an alloy of the BCC structure including Fe or Co as a principal component, said alloy being formed on a second plane of said tunnel barrier layer, said method comprising:
growing said single-crystalline MgO (001) layer under conditions such that the density of dislocation defects in said single-crystalline MgO (001) layer is not more than the density at which the spin scattering of tunneling electron caused by magnons at the interface of said ferromagnetic electrode layers is suppressed.

23. A method of manufacturing a magnetic tunnel junction device comprising:
a tunnel barrier layer comprising a single-crystalline MgO (001);
a first single-crystalline ferromagnetic material layer comprising an alloy of the BCC structure formed on a first plane of said tunnel barrier layer and including Fe or Co as a principal component; and
a second single-crystalline ferromagnetic material layer comprising an alloy of the BCC structure including Fe or Co as a principal component, said alloy being formed on a second plane of said tunnel barrier layer, said method comprising:
growing said single-crystalline MgO (001) layer under conditions including at least one of the following conditions: a condition in which the film-deposition rate is reduced; a condition in which the substrate temperature during film deposition is increased; and a condition in which an underlayer is made flat on an atomic level.

24. A method of manufacturing a magnetic tunnel junction device comprising:
a tunnel barrier layer comprising a single-crystalline MgO (001);
a first single-crystalline ferromagnetic material layer comprising an alloy of the BCC structure formed on a first plane of said tunnel barrier layer and including Fe or Co as a principal component; and
a second single-crystalline ferromagnetic material layer comprising an alloy of the BCC structure including Fe or Co as a principal component, said alloy being formed on a second plane of said tunnel barrier layer, said method comprising:
growing said single-crystalline MgO (001) layer under conditions such that the density at which crystalline nuclei develop in the initial phase of growth of said single-crystalline MgO (001) layer (to be hereafter referred to as “a nucleus development density”) is controlled to be not more than the density of dislocation defects at which the spin scattering of tunneling electron caused by magnons at the interface of said ferromagnetic electrode layers is suppressed.

25. The method of manufacturing a magnetic tunnel junction device according to claim 24, comprising growing said single-crystalline MgO (001) layer under conditions including at least one of the following conditions: a condition in which the film-deposition rate is reduced; and a condition in which an underlayer is made flat on an atomic level.
